(19) United States
(12) Patent Application Publication
(10) Pub. No.: US 2022/0159864 A1
(43) Pub. Date: May 19, 2022

(54) STORAGE APPARATUS, STORAGE-APPARATUS MANAGEMENT SYSTEM, AND STORAGE-APPARATUS MANAGEMENT METHOD

(71) Applicant: Panasonic Intellectual Property Management Co., Ltd., Osaka (JP)

(72) Inventors: Masaru NIKAIDO, Gunma (JP); Osamu NARA, Saitama (JP); Tomohiro IMAI, Saitama (JP); Ryuji SUGIZAKI, Saitama (JP)

(21) Appl. No.: 17/525,595

(22) Filed: Nov. 12, 2021

(30) Foreign Application Priority Data
Nov. 13, 2020 (JP) 2020-189757
Nov. 13, 2020 (JP) 2020-189758

(51) Int. Cl. H05K 7/14; H05K 5/02

(52) U.S. Cl. CPC H05K 7/1488; H05K 5/0221; H05K 7/1487

(57) ABSTRACT

A storage apparatus includes: a display room 4 having an opening 4A open to the front and capable of storing an article inside; an input unit into which specified information associated with the article is inputted; and a control unit that associates the display room 4 with the specified information, and the control unit cancels the associated relation between the display room 4 and the specified information in a case in which a specified time has elapsed since the control unit received a specified signal.

### INCORPORATION BY REFERENCE

The present application claims priority under 35 U.S.C. § 119 to Japanese Patent Application No. 2020-189758 filed on Nov. 13, 2020 and Japanese Patent Application No. 2020-189757 filed on Nov. 13, 2020. The content of the applications is incorporated herein by reference in its entirety.

### BACKGROUND OF THE INVENTION

### Field of the Invention

The present invention relates to a storage apparatus, a storage-apparatus management system, and a storage-apparatus management method.

### Description of the Related Art

Japanese Patent Laid-Open No. 2006-184965 discloses a product sales-display case that prevents a situation in which products cannot be sold.

This product sales-display case includes a front door for opening and closing a front opening of the body case, locking means for locking the front door, purchase-request obtaining means for obtaining a purchase request for a product from a purchaser, and product discharging means capable of delivering the product placed on a product display shelf based on the purchase request obtained by the purchase-request obtaining means. This product sales-display case further includes detection means for detecting whether the front door is locked and control means that, in the case in which the detection result by the detection means indicates that the front door is locked, controls the purchase-request obtaining means such that the purchase-request obtaining means can obtain the purchase request.

### SUMMARY OF THE INVENTION

The present disclosure provides a storage apparatus capable of preventing a situation in which articles are stored continuously inside a display room.

A storage apparatus in the present disclosure includes: a display room having an opening open to the front and capable of storing an article inside; an input unit into which specified information associated with the article is inputted; and a control unit that associates the display room with the specified information, and the control unit cancels the associated relation between the display room and the specified information in a case in which a specified time has elapsed since the control unit received a specified signal.

The storage apparatus in the present disclosure is capable of canceling the associated relation between the specified information associated with an article that has been stored inside a display room for a time exceeding the specified time and the display room. Thus, the storage apparatus can prevent a situation in which the articles stored in a display room are stored continuously inside the display room, and this enables effective use of the display room.

### BRIEF DESCRIPTION OF THE DRAWINGS

FIG. 1 is a perspective view of a storage apparatus of Embodiment 1;

FIG. 2 is a perspective view of the storage apparatus of Embodiment 1 with illustration of the outer doors omitted;

FIG. 3 is a block diagram illustrating the configuration of the storage apparatus of Embodiment 1;

FIG. 4 is a diagram illustrating a schematic configuration of a storage-apparatus management system of Embodiment 1;

FIG. 5 is a sequence diagram illustrating operation of the storage-apparatus management system of Embodiment 1;

FIG. 6 is a flowchart illustrating operation of the storage apparatus of Embodiment 1;

FIG. 7 is a diagram illustrating a schematic configuration of a storage-apparatus management system of Embodiment 2;

FIG. 8 is a sequence diagram illustrating operation of the storage-apparatus management system of Embodiment 2; and

FIG. 9 is a sequence diagram illustrating operation of the storage-apparatus management system of Embodiment 2.

### DETAILED DESCRIPTION OF THE PREFERRED EMBODIMENTS

(Underlying Knowledge of Present Disclosure and Some Other Information)

At that time when the inventors conceived the present disclosure, a product sales-display case that prevents a situation in which products could not be sold had been disclosed.

This product sales-display case functions as what is called a storage apparatus for sale and includes a front door for opening and closing the front opening of the body case, locking means for locking the front door, purchase-request obtaining means for obtaining purchase requests for products from purchasers, and product discharging means capable of delivering products placed on product display shelves based on purchase requests obtained by the purchase-request obtaining means.

For such a product sales-display case, when a purchaser, what is called a user, inputs specified information, the front door is unlocked, and this enables this purchaser to open the front door and take out a product or an article stored inside.

However, in the case in which the foregoing storage apparatus has a plurality of articles stored in it, there is a problem that a state occurs in some cases in which the purchaser does not take out a product or article to be taken out, in other words, a state of forgetting to take out occurs in some cases. The inventors, finding this problem, conceived the subjects of the present disclosure to solve the problem.

In view of the above point, the present disclosure provides a storage apparatus capable of preventing a state in which articles are stored continuously inside a display room and also capable of determining whether an article stored in the display room has been taken out.

Hereinafter, embodiments will be described in detail with reference to the drawings. However, detailed description more than necessary may be omitted. For example, detailed description of things already well known or repetitive description of substantially the same configurations may be omitted. This is to avoid the following description becoming redundant more than necessary and to make it easy for those skilled in the art to understand.

Note that the attached drawings and following description are provided to help those skilled in the art understand the present disclosure sufficiently and thus are not intended to limit the subjects described in the claims.

### Embodiment 1

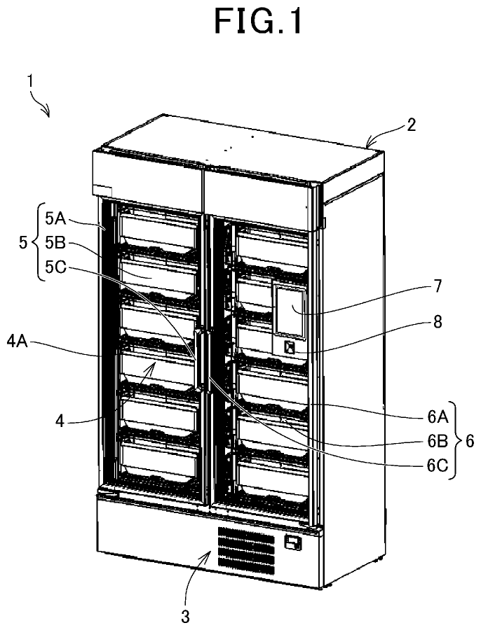

Hereinafter, an embodiment will be described with reference to FIGS. 1 to 6.

[1-1. Configuration]

[1-1-1. Configuration of Storage Apparatus]

FIG. 1 is a perspective view of a storage apparatus 1 according to the embodiment.

The storage apparatus 1 is one for refrigeration capable of keeping articles stored inside at a specified temperature. Note that the storage apparatus 1 is not limited to this configuration but may be one capable of keeping articles stored inside in room temperature. In addition, for example, the storage apparatus 1 may be one capable of keeping articles in a frozen state. The storage apparatus 1 can be used as a sales storage apparatus for displaying and selling articles or a locker for receiving articles. The storage apparatus 1 is installed at store premises or the like such as supermarkets or convenience stores.

The storage apparatus 1 of the present embodiment is what is called a reach-in storage apparatus having openable door members on the front face.

As illustrated in FIG. 1, the storage apparatus 1 has a box-shaped casing 2 having a heat-insulating wall on each side face. The casing 2 includes a machine room 3 at a lower portion and a display room 4 above the machine room 3.

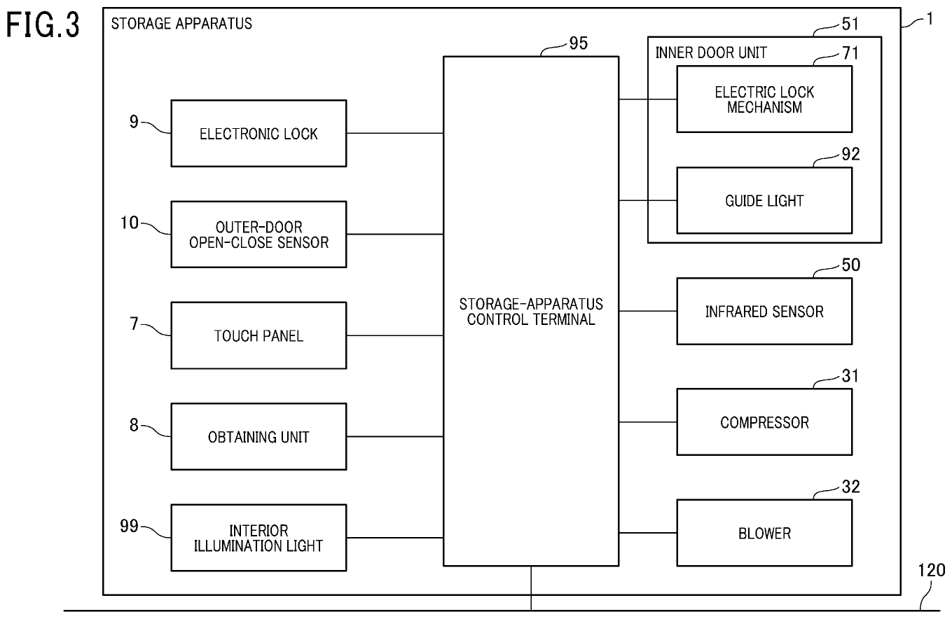

The machine room 3 stores the devices composing a refrigeration circuit (refrigerant circuit), such as a compressor 31 (FIG. 3), a condenser, an expander, and an evaporator, and a blower 32 (FIG. 3) that feeds cold air obtained by heat exchange with the evaporator into the display room 4. These devices operate to adjust the temperature in the display room 4.

Specifically, the cold air cooled in the machine room 3 is guided through a not-illustrated cold-air duct to an upper portion of the display room 4, and the cold air is introduced into the display room 4 from the upper portion. The cold air introduced in the display room 4 cools the display room 4, and then returns to the machine room 3. The cold air can circulate inside the casing 2.

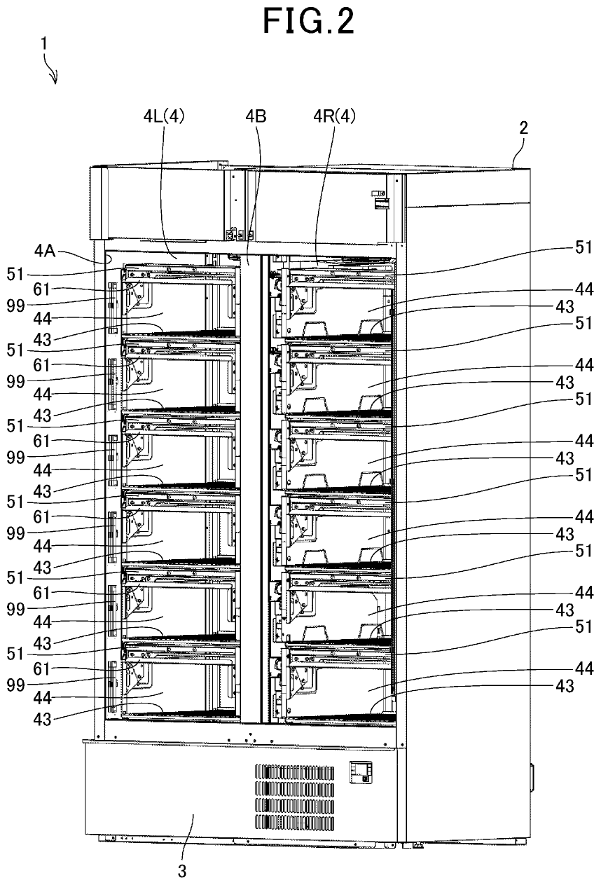

FIG. 2 is a perspective view of the storage apparatus 1 with illustration of the outer doors 5 and 6 omitted.

As illustrated in FIG. 2, an opening 4A open to the front is formed on the front face of the display room 4. At an approximately center of this opening 4A in the width direction is provided a partitioning member 4B. This partitioning member 4B is a columnar member extending along the up-down direction of the opening 4A. Both ends of the partitioning member 4B are respectively connected to the upper edge and lower edge of the opening 4A.

As illustrated in FIG. 1, the opening 4A is closed by the outer doors 5 and 6 which are paired in the width direction and capable of opening and closing. The outer doors 5 and 6 are rotatably supported at their upper ends and lower ends with hinges by the right and left outer edges of the opening 4A, respectively. The outer doors 5 and 6 are what are called double doors.

The outer doors 5 and 6 include rectangular frame members 5A and 6A, transparent plates 5B and 6B fitted in the frame members 5A and 6A, and handles 5C and 6C provided at portions of the outer doors 5 and 6 that come close to each other when the outer doors 5 and 6 are closed.

The portions of the outer doors 5 and 6 that come close to each other when the outer doors 5 and 6 are closed both come into contact with the partitioning member 4B. Thus, in front view of the storage apparatus 1, the partitioning member 4B is positioned between the outer doors 5 and 6 when the outer doors 5 and 6 are closed.

The storage apparatus 1 has a configuration in which the inside of the display room 4 can be seen from the outside through the transparent plates 5B and 6B in the state in which the outer doors 5 and 6 are closed.

The outer doors 5 and 6 are provided with an electronic lock 9 (FIG. 3) and an outer-door open-close sensor 10 (FIG. 3). The electronic lock 9 is a lock mechanism that electrically locks and unlocks. When this electronic lock 9 is locked, the outer doors 5 and 6 are kept in a state in which they cannot be opened.

The outer-door open-close sensor 10 functions as a door-open-close detection unit that detects whether the outer doors 5 and 6 are opened or closed. The outer-door open-close sensor 10 is, for example, a sensor part, such as a proximity sensor provided near the outer doors 5 and 6.

On the front face of the right outer door 6 is provided a touch panel 7 that functions as an input unit and a display unit. The touch panel 7 not only functions as a display unit that displays various kinds of information but also functions as an operation unit capable of touch operation with which various kinds of information such as setting information for the storage apparatus 1 can by inputted by touching the part where the information is displayed.

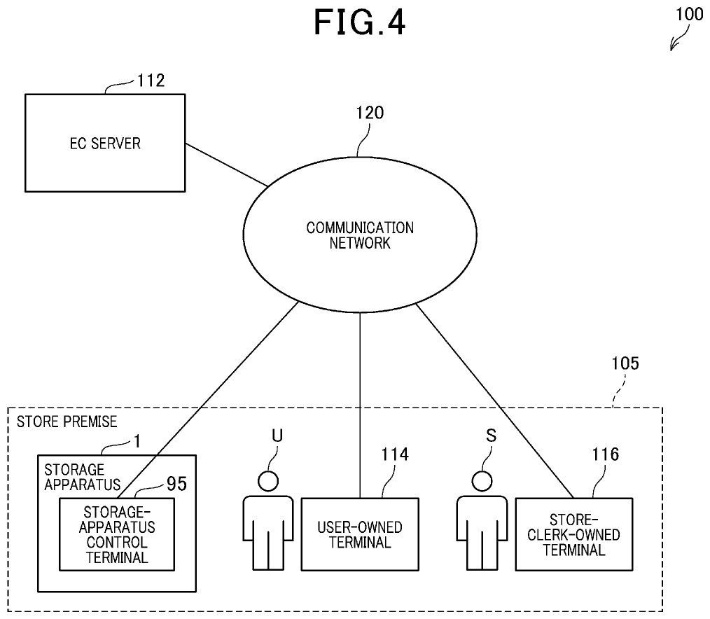

Below the touch panel 7 is provided an obtaining unit 8 that obtains specified information. The obtaining unit 8 of the present embodiment obtains, for example, from a user-owned terminal 114 (FIG. 4) which is a mobile information terminal owned by a user who uses the storage apparatus 1, specified information such as authentication information assigned to this terminal. In other words, the obtaining unit 8 function as an input unit for various kinds of information.

Specified information in the present embodiment is information indicating specified articles.

The obtaining unit 8 of the present embodiment is a reading device (camera) that reads what is called two-dimensional codes such as QR codes (registered trademark). The obtaining unit 8 is capable of reading, for example, two-dimensional codes displayed on the display units of mobile information terminals or two-dimensional codes printed on various print media.

In other words, media used to show specified information in the present embodiment are two-dimensional codes.

Hence, the obtaining unit 8 in the present embodiment is a reading device capable of reading two-dimensional codes.

When the obtaining unit 8 obtains a two-dimensional code, the obtaining unit 8 transmits a specified signal indicating that it has obtained the two-dimensional code to a storage-apparatus control terminal 95 (FIG. 3) included in the storage apparatus 1.

Note that the obtaining unit 8 may be a device that reads, from recording media such as various electronic tags, information recorded on the recording media. In this case, the obtaining unit 8 may have a function as a transmission-reception unit that writes information on various recording media.

The display room 4 is partitioned by the partitioning member 4B into a left display room 4L and a right display room 4R.

As described above, the portions of the outer doors 5 and 6 that come close to each other when the outer doors 5 and 6 are closed both come into contact with the partitioning member 4B. Thus, the outer door 5 closes the front face of the left display room 4L, and the outer door 6 closes the right display room 4R.

The right and left display rooms 4L and 4R have in their insides a plurality of shelf plates 43 provided at intervals along the up-down direction of the display rooms 4L and 4R. In the present embodiment, each shelf plate 43 is a flat plate member in the form of a mesh plate.

The display rooms 4L and 4R are partitioned (divided) by these shelf plates 43, so that each of the display rooms 4L and 4R has a plurality of container compartments 44 each having the bottom portion formed of the shelf plate 43. The container compartment 44 is capable of storing an article. The article stored in this container compartment 44 is placed on the shelf plate 43.

In the present embodiment, the container compartments 44 are formed in two rows in the right-left direction (the width direction) and six tiers in the up-down direction, but the number of container compartments 44 may be any number as appropriate.

FIG. 3 is a block diagram illustrating the configuration of the storage apparatus 1.

As illustrated in FIG. 3, each container compartment 44 of the right and left display rooms 4L and 4R is provided with an infrared sensor 50. These infrared sensors 50 each include a light emitting unit that emits infrared light and a light receiving unit that receives infrared light emitted by the light emitting unit. These light emitting unit and light receiving unit are provided such that the article stored in the container compartment 44 is placed between the light emitting unit and the light receiving unit.

With this configuration, when an article is stored inside the container compartment 44, the infrared sensor 50 detects that the infrared light emitted by the light emitting unit is blocked. When an article is not stored inside the container compartment 44, the infrared sensor 50 detects that the infrared light emitted by the light emitting unit is received by the light receiving unit.

In other words, the infrared sensor 50 functions as an article detection unit capable of detecting the internal state of the container compartment 44.

Note that the article detection unit is not limited to the infrared sensor 50 but may be other detectors or detection devices such as for example, a TOF sensor, an ultrasonic sensor, or a camera. Alternatively, for example, the article detection unit may be a weight sensor attached to the shelf plate 43 or the like and capable of measuring the weight of the article placed on the shelf plate 43. In addition, for example, the storage apparatus 1 may have a sensor for detecting the opening and closing of an inner door 61 and determine whether an article is stored inside the container compartment 44, by the opening and closing of the inner door detected by this sensor.

Further, each container compartment 44 may have an article detection unit formed by combining some of the foregoing various sensors, and they may be used in parallel.

Each container compartment 44 is provided with an inner door unit 51. The inner door unit 51 supports the inner door 61 (the door of the container compartment) for closing the front face of the container compartment 44 such that the inner door 61 is rotatable, and the rotation of this inner door 61 opens or closes the front face of the container compartment 44.

The inner door 61 (the door of the container compartment) is a flat plate member having approximately the same shape as the front face of the container compartment 44, and the inner door 61 is disposed to closes the front face of the container compartment 44 by the inner door unit 51.

In the present embodiment, the inner door 61 is supported by the inner door unit 51 to be rotatable along the up-down direction of the container compartment 44. The inner door 61 moves between a closed position at which the front face of the container compartment 44 is closed by the inner door 61 and an open position at which the front face of the container compartment 44 is open. Note that in FIG. 2 each inner door 61 is at the open position.

For the storage apparatus 1, when a user or a management worker such as a store clerk puts in or takes out articles, he/she opens one or both of the outer doors 5 and 6 depending on the positions of the container compartments 44 in his/her intention and also opens the inner doors 61 of the container compartments 44.

The inner door unit 51 is provided with an electric lock mechanism 71 and a guide light 92.

The electric lock mechanism 71 electrically locks and unlock the inner door 61. By driving of the electric lock mechanism 71, the inner door 61 placed at the closed position is fixed at this closed position (specified position). In other words, when the electric lock mechanism 71 is locked, the inner door 61 is kept in a state in which the inner door 61 cannot be opened.

The guide light 92 includes, for example, a light emitting diode (LED) light source which is an electrical part. Turning-on of the guide light 92 can notify the user of the state of the container compartment 44.

Note that the inner door unit 51 may have a driving mechanism that rotates the inner door 61.

As illustrated in FIG. 2, the display room 4 has interior illumination lights 99 in its inside. The interior illumination lights 99 are illumination devices that supplementarily illuminate the inside of the display room 4. For the light source of this interior illumination light 99, various linear light sources are used including discharge lamps such as fluorescent lights and LEDs arranged linearly.

In the present embodiment, a plurality of the interior illumination lights 99 are provided to each of the inner side surfaces positioned in the right-left direction out of the inner side surfaces of the casing 2 surrounding the display room 4. In these inner side surfaces, each interior illumination light 99 is positioned on the front side of the corresponding inner door 61 (the opening 4A side) in the display room 4. In other words, each interior illumination light 99 is disposed at a position adjacent to the corresponding container compartment 44.

[1-1-2. Configuration of Storage-Apparatus Control Terminal]

As illustrated in FIG. 3, the storage apparatus 1 includes the storage-apparatus control terminal 95.

The storage-apparatus control terminal 95 includes a computer having a processor such as a CPU or an MPU and a memory device such as ROM or RAM, and controls each unit of the storage apparatus 1.

The storage-apparatus control terminal 95 functions as a control unit that controls each unit of the storage apparatus 1 by the processor executing a program stored in the memory device.

The storage-apparatus control terminal 95 has a function as a communication unit such as a signal transmitter-receiver having a reception circuit and a transmission circuit. In the present embodiment, the storage-apparatus control terminal 95 is communicably connected to an external communication network 120. In other words, the storage-apparatus control terminal 95 functions as a communication unit of the storage apparatus 1. The storage-apparatus control terminal 95 is also capable of receiving specified signals transmitted from each unit of the storage apparatus 1.

The storage-apparatus control terminal 95 has a storage unit capable of storing various kinds of information obtained via the communication network 120 and the like and specified signals received from each unit of the storage apparatus 1. In the present embodiment, the foregoing memory device functions as a storage unit of the storage-apparatus control terminal 95.

The storage-apparatus control terminal 95 controls the operation of the devices included in the refrigeration circuit, for example, controlling the number of revolutions of the compressor 31 and the blower 32, to keep the temperature inside the display room 4 at a set temperature.

Note that the configuration is not limited to this, but in the storage apparatus 1, the temperature set for the temperature inside the display room 4 may be controlled by a control device such as a controller or the like provided separately form the storage-apparatus control terminal 95.

The electronic lock 9 is electrically connected to the storage-apparatus control terminal 95. The storage-apparatus control terminal 95 controls locking and unlocking of this electronic lock 9.

The outer-door open-close sensor 10 is also electrically connected to the storage-apparatus control terminal 95. The storage-apparatus control terminal 95 obtains the detection result of the outer-door open-close sensor 10 to obtain the open/closed states of the outer doors 5 and 6.

Note that the configuration is not limited to this, but the outer-door open-close sensor 10 may be, for example, one that detects whether the outer doors 5 and 6 are open or closed by receiving signals for executing locking and unlocking of the electronic lock 9.

The storage-apparatus control terminal 95 is electrically connected to the electric lock mechanism 71 of each inner door unit 51. The storage-apparatus control terminal 95 is capable of controlling driving of the electric lock mechanisms 71. With this configuration, the storage-apparatus control terminal 95 controls locking and unlocking of the inner doors 61 of the container compartments 44.

The storage-apparatus control terminal 95 is capable of communicating with each of the touch panel 7 and the obtaining unit 8.

The storage-apparatus control terminal 95 functions as a determination unit that when receiving, for example, information inputted by operations on the touch panel 7 or authentication information obtained by the obtaining unit 8, determines whether the received authentication information matches various kinds of preset authentication information. In the present embodiment, authentication information is in the form of a two-dimensional code.

Note that the form of authentication information is not limited to two-dimensional codes but may be information of other forms such as signal transmission and reception by wireless communication, barcodes, various types of biometric authentication, manual input by using the touch panel 7, and voice input.

Further, the storage-apparatus control terminal 95 performs display control of the touch panel 7 to display a screen that shows various kinds of information related to the storage apparatus 1 and the storage-apparatus control terminal 95. For example, the storage-apparatus control terminal 95 displays a message for notifying that the outer doors 5 and 6 or each inner door 61 is unlocked, or it displays an error message when a two-dimensional code presented to the obtaining unit 8 is invalid.

In addition, after a user U does actions related to receiving purchased articles to the storage apparatus 1, if there remains an article in the display room 4, determined to be what the user U forgot to receive, the storage-apparatus control terminal 95 displays a screen on the touch panel 7 indicating that there remains an article that the user U forgot to receive.

Thus, the touch panel 7 in the present embodiment functions as a notification unit that notifies the user U that there remains an article that the user U forgot to receive.

The storage-apparatus control terminal 95 controls turning-on of the guide lights 92 and the interior illumination lights 99. Specifically, based on information inputted from the touch panel 7 and the obtaining unit 8, the storage-apparatus control terminal 95 turns on or off the guide lights 92 and the interior illumination lights 99 or switching them in a specified pattern. The storage-apparatus control terminal 95 is capable of controlling the guide lights 92 and the interior illumination lights 99 independently.

The storage-apparatus control terminal 95 is electrically connected to the infrared sensors 50 and capable of obtaining the detection results by the infrared sensors 50.

Then, the storage-apparatus control terminal 95 functions as a determination unit that determines, based on the detection results, the internal state of each container compartment 44, in other words, whether an article is stored inside the container compartment 44 for which the storage-apparatus control terminal 95 received the detection results.

Specifically, if the storage-apparatus control terminal 95 obtains, from an infrared sensor 50, the detection result indicating that the infrared light emitted by the light emitting unit is blocked, it determines that an article is stored inside the container compartment 44.

If the storage-apparatus control terminal 95 obtains, from an infrared sensor 50, the detection result indicating that the infrared light emitted by the light emitting unit is received by the light receiving unit, it determines that an article is not stored inside the container compartment 44.

With this operation, the storage-apparatus control terminal 95 can determine whether an article is stored inside each container compartment 44.

In addition, the storage-apparatus control terminal 95 is also capable of storing determination results indicating whether an article is stored inside each container compartment 44. With this operation, the storage-apparatus control terminal 95 can obtain the inventory condition of the storage apparatus 1.

Further, the storage-apparatus control terminal 95 is capable of displaying the obtained inventory condition on the touch panel 7.

The storage-apparatus control terminal 95 is capable of associating a specified two-dimensional code obtained by the obtaining unit 8 with one of the container compartments 44 and storing the associated relation.

Specifically, when an operation for designating the two-dimensional code obtained by the obtaining unit 8 to a specified container compartment 44 is inputted to the touch panel 7, the storage-apparatus control terminal 95 associates the specified two-dimensional code obtained by the obtaining unit 8 with the designated the container compartment 44 and also stores this associated relation.

With this operation, the storage-apparatus control terminal 95 can store information which container compartment 44 the article associated with a two-dimensional code is stored in.

The specified information in the present embodiment is information indicating a specified article and a specified container compartment 44 in which the specified article is stored, by the foregoing operation of the storage-apparatus control terminal 95.

Further, the storage-apparatus control terminal 95 is capable of determining whether a two-dimensional code obtained by the obtaining unit 8 is associated with any of the container compartments 44.

The storage-apparatus control terminal 95, based on the determination result indicating whether an article is stored inside each container compartment 44, can cancel the associated relation between specified two-dimensional codes obtained by the obtaining unit 8 and the corresponding container compartments 44.

Specifically, in the case in which the storage-apparatus control terminal 95, based on the detection result by the infrared sensor 50, determines that an article is not stored inside a specified container compartment 44, the storage-apparatus control terminal 95 cancels the associated relation between this container compartment 44 and the two-dimensional code associated with this container compartment 44.

With this operation, the storage-apparatus control terminal 95 can change the status of the container compartment 44 from which an article was taken out to a container compartment 44 in which an article is not stored, in other words, to a vacant container compartment 44, and store the status without waiting for a specified time. Thus, for the storage apparatus 1, for example, a management worker who manages the storage apparatus 1 can put a new article into the storage apparatus 1 without waiting a specified time.

Note that the storage-apparatus control terminal 95 keeps the associated relations between the container compartments 44 determined to be storing an article inside and the two-dimensional codes associated with these container compartments 44.

The storage-apparatus control terminal 95 can associate a specified two-dimensional code obtained by the obtaining unit 8 with a plurality of container compartments 44. With this configuration, for example, in the case in which a plurality of articles are associated with one two-dimensional code, these articles can be stored using a plurality of container compartments 44.

This prevents, for example, a situation in which, when a worker needs to store a large number of articles associated with one two-dimensional code into the storage apparatus 1, the worker cannot store these articles into the storage apparatus 1 because these articles cannot be stored into one container compartment 44. In other words, since in the storage apparatus 1, a two-dimensional code can be associated with a plurality of container compartments 44, a plurality of articles associated with one two-dimensional code can be stored into a plurality of container compartments 44.

Further, in the case in which a specified two-dimensional code obtained by the obtaining unit 8 is associated with a plurality of container compartments 44, the storage-apparatus control terminal 95 determines whether each of these container compartments 44 stores an article inside.

For the container compartments 44 determined to be not storing an article inside, the storage-apparatus control terminal 95 cancels the associated relation between those container compartments 44 and the two-dimensional code associated with these container compartments 44. For the container compartments 44 determined to be storing an article inside, the storage-apparatus control terminal 95 keeps the associated relation between those container compartments 44 and the two-dimensional code associated with these container compartments 44.

With this operation, in the case in which a specified two-dimensional code is associated with a plurality of container compartments 44, and some of these container compartments are determined to be container compartments 44 from which articles have been taken out, it is possible to change the statuses of the container compartments 44 to vacant container compartments 44 and store the new statuses without waiting for a specified time.

As described above, the storage-apparatus control terminal 95 functions as a management unit that manages the two-dimensional codes associated with articles stored in the storage apparatus 1.

The storage-apparatus control terminal 95 has a function as a time measurement unit that measures time.

Specifically, the storage-apparatus control terminal 95 is capable of measuring the time that has elapsed from the time when receiving specified signals, from the time when obtaining specified information, or from the time when transmitting specified signals.

Then, using this function as the time measurement unit, the storage-apparatus control terminal 95 can cancel the associated relation between container compartments 44 and the two-dimensional codes associated with these container compartments 44.

Specifically, in the case in which a specified time has elapsed since the obtaining unit 8 first obtained the two-dimensional code associated with a specified container compartment 44, the storage-apparatus control terminal 95 cancels the associated relation between this container compartment 44 and the two-dimensional code associated with this container compartment 44. Then, for example, the storage-apparatus control terminal 95 indicates, on the display of the touch panel 7, the container compartment 44 with which the associated relation of the two-dimensional code has been canceled.

This operation can prompt a management worker who saw this display to withdraw the article stored in the container compartment 44 with which the associated relation has been canceled. Thus, the storage apparatus 1 can prevents a situation in which specified articles are stored inside the display room 4 for a long time.

In the present embodiment, based on the determination result indicating whether an article is stored inside each container compartment 44 and the time measured by the time measurement unit, the storage-apparatus control terminal 95 cancels the associated relations between specified two-dimensional codes obtained by the obtaining unit 8 and the container compartments 44.

Note that the storage-apparatus control terminal 95 may be provided separately from the storage apparatus 1. In this case, the storage apparatus 1 is provided with a communication unit capable of communicating with the storage-apparatus control terminal 95.

[1-1-3. Configuration of Storage-Apparatus Management System]

FIG. 4 is a diagram illustrating a schematic configuration of a storage-apparatus management system 100 of the embodiment.

The storage-apparatus management system 100 processes information for managing the storage apparatus 1. The storage-apparatus management system 100 includes the storage apparatus 1 and an EC server (computer) 112. The present embodiment is described based on a case in which the system includes one storage apparatus 1 and one server 1, but the configuration is not limited to this. The number of apparatuses and servers managed by the storage-apparatus management system 100 may be plural.

The communication network 120 connects the devices included in the storage-apparatus management system 100, such as the storage apparatus 1 and the EC server 112, so that these devices can perform data communication with one another. The communication network 120 may include public line networks, dedicated lines, and various wireless communication lines and may also include devices such as servers, routers, and wireless communication access points. The connection between the devices included in the storage-apparatus management system 100 and the communication network 120 may be wireless or may be wired.

The EC server 112 provides EC websites (EC sites) for purchasing products or the like through electronic commerce (EC).

The EC server 112 can communicate with various terminals, such as smartphones, and servers via the communication network 120, and the EC server 112 can receive purchasing or orders of articles from various terminals and transmit two-dimensional codes associated with these articles to the terminals.

The EC server 112 can also make specified notifications to various terminals.

Note that the storage-apparatus management system 100 may include not only the EC server 112 but also various web servers, local servers, and the like.

In the storage-apparatus management system 100 of the present embodiment, the storage apparatus 1 is installed at a store premise 105 such as a convenience store or a concession stand.

The storage-apparatus control terminal 95 controls each unit of the storage apparatus 1 as described above.

The storage-apparatus management system 100 can receive connection from a user-owned terminal 114 owned by a user U who purchases an article stored inside the storage apparatus 1 and a store-clerk-owned terminal 116 owned by a store clerk S. The user-owned terminal 114 and the store-clerk-owned terminal 116 have data communication functions and perform data communication with the storage apparatus 1 and the foregoing servers.

The user-owned terminal 114 and the store-clerk-owned terminal 116 are mobile terminals capable of communicating with the EC server 112 to perform purchase processing for articles, and these user-owned terminal 114 and store-clerk-owned terminal 116 are, for example, mobile phones, smartphones, tablets, or the like.

These user-owned terminal 114 and store-clerk-owned terminal 116 can execute specified application programs related to the storage-apparatus management system 100. In the present embodiment, these the user-owned terminal 114 and store-clerk-owned terminal 116 are capable of displaying two-dimensional codes which are the specified information.

Here, in the storage-apparatus management system 100, the store clerk S is a management worker who manages the storage apparatus 1 and articles stored in the storage apparatus 1. The store clerk S is, for example, a store clerk working at the store premise 105, an installation worker who installs the storage apparatus 1, a management worker for managing the storage apparatus 1 and the storage-apparatus management system 100, or a like worker. In other words, the store clerk S is a worker who provides maintenance of the storage apparatus 1, puts and takes articles into and out of the storage apparatus 1, and manages the inventory of stored articles.

The store-clerk-owned terminal 116 is capable of displaying authentication information that identifies the store clerk S. In the present embodiment, the authentication information is in the form of a two-dimensional code.

The user U uses various services provided by the storage apparatus 1 and/or the storage-apparatus management system 100, such as purchasing an article stored in the storage apparatus 1.

Note that the number of user-owned terminals 114 and the number of store-clerk-owned terminals 116 included in the storage-apparatus management system 100 are not limited to any specific ones.

[1-2. Operation]

The operation of the storage apparatus 1 and the storage-apparatus management system 100 having the configurations described above will be described below.

[1-2-1. Operation when Article is Purchased and Put into Storage Apparatus]

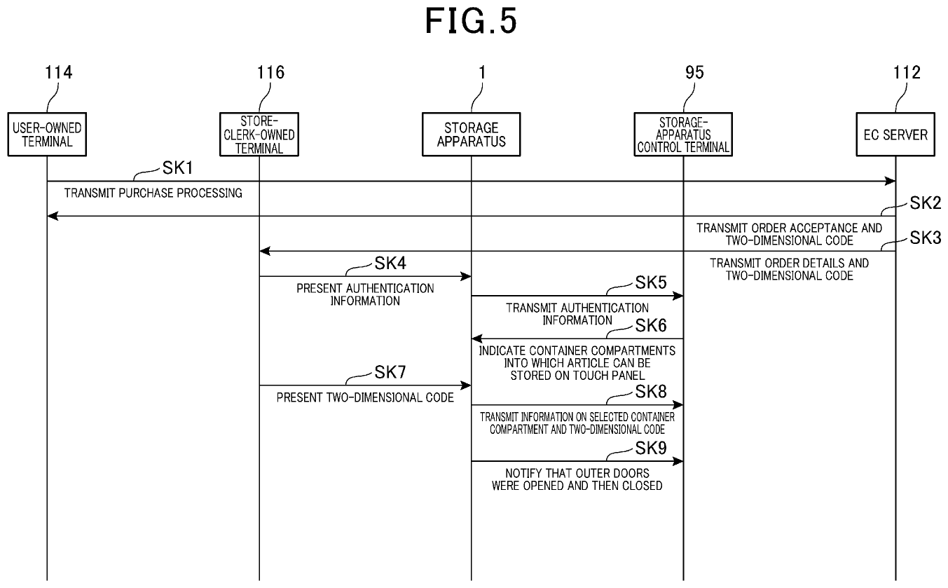

FIG. 5 is a sequence diagram illustrating operation of the storage-apparatus management system 100.

Based on FIG. 5, a description will be given of the operation of the storage-apparatus management system 100 for the case in which an article is purchased and put into the storage apparatus 1.

First, when the user U orders an article, the user U uses the user-owned terminal 114 to communicate with the EC server 112, and performs purchase processing for an article, according to displays and instructions on the EC site (step SK1).

When the EC server 112 receives the purchase processing transmitted from the user-owned terminal 114, the EC server 112 transmits information indicating that the purchase processing has been accepted, in other words, an order acceptance, to the user-owned terminal 114. The EC server 112 transmits, along with the order acceptance, a two-dimensional code associated with the article purchased by the user U to the user-owned terminal 114 (step SK2).

Further, the EC server 112 transmits, to the store-clerk-owned terminal 116, information on the article purchased by the user U, in other words, the order details, and a two-dimensional code associated with the article purchased by the user U (step SK3).

When the store clerk S receives the order details and the two-dimensional code, the store clerk S presents authentication information that identifies the store clerk S to the obtaining unit 8 (step SK4).

Obtaining the authentication information, the obtaining unit 8 transmits the authentication information to the storage-apparatus control terminal 95 (step SK5).

Obtaining the authentication information, the storage-apparatus control terminal 95 unlocks the electronic lock 9 and indicates, on the touch panel 7, the container compartments 44 in which an article is not stored, in other words, the container compartments 44 into which an article can be stored (step SK6).

The store clerk S opens the outer doors 5 and 6 and puts the article into a specified container compartment 44 according to the display of the touch panel 7, in other words, the store clerk S does storing work. When the storing work is completed, the store clerk S closes the outer doors 5 and 6 and presents the two-dimensional code that the store-clerk-owned terminal 116 has received to the obtaining unit 8 (step SK7).

The storage-apparatus control terminal 95 obtains the detection results by the infrared sensors 50, in other words, the container compartment 44 selected to put in the article, and the two-dimensional code obtained by the obtaining unit 8 (step SK8).

Further, when the storage-apparatus control terminal 95 obtains a signal indicating that the outer doors 5 and 6 were opened and then closed from the outer-door open-close sensor 10 (step SK9), the storage-apparatus control terminal 95 associates the container compartment 44 selected to put in the article and the two-dimensional code obtained by the obtaining unit 8.

[1-2-2. Operation when Article is Taken Out of Storage Apparatus]

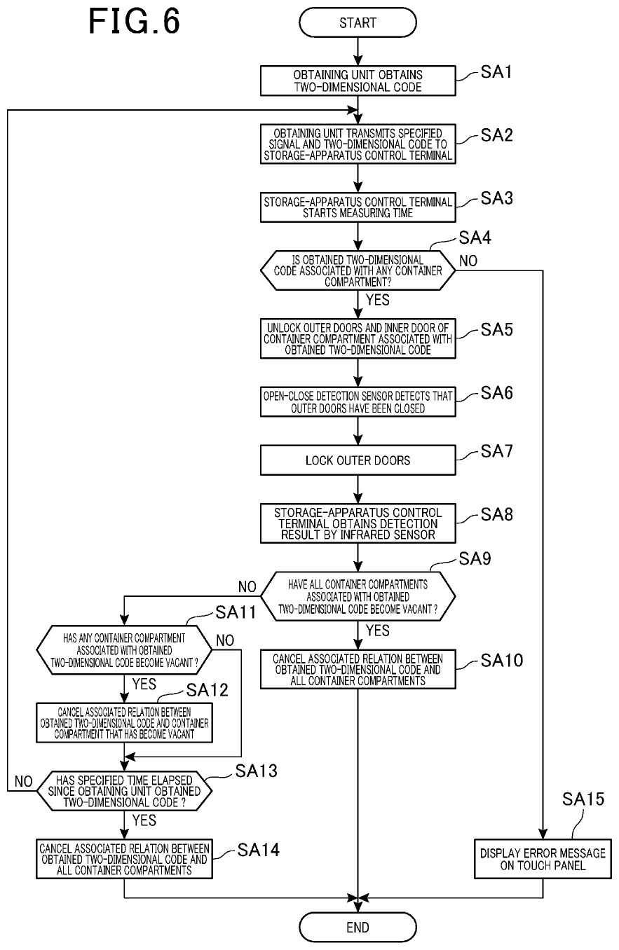

FIG. 6 is a flowchart illustrating operation of the storage apparatus 1.

Based on FIG. 6, a description will be given of the operation of the storage apparatus 1 for the case in which an article is taken out of the storage apparatus 1.

First, for the user U to receive an article from the storage apparatus 1, the user U presents a two-dimensional code displayed on the user-owned terminal 114 to the obtaining unit 8 of the storage apparatus 1.

When the obtaining unit 8 obtains the presented two-dimensional code (step SA1), the obtaining unit 8 transmits a specified signal indicating that the obtaining unit 8 has obtained the two-dimensional code and the obtained two-dimensional code to the storage-apparatus control terminal 95 (step SA2).

Receiving the specified signal at step SA2, the storage-apparatus control terminal 95 starts measuring time (step SA3).

Then, the storage-apparatus control terminal 95 determines whether the two-dimensional code obtained by the obtaining unit 8 is associated with any of the container compartments 44 (step SA4).

If the obtained two-dimensional code is associated with a specified container compartment 44 (step SA4: YES), the storage-apparatus control terminal 95 controls the electronic lock 9 and the specified electric lock mechanism 71 to unlock the outer doors 5 and 6 and the inner door 61 of the container compartment 44 associated with this two-dimensional code (step SA5).

When the electronic lock 9 and the electric lock mechanism 71 are unlocked at step SA5, the user U opens the outer doors 5 and 6 and the inner door 61 of the container compartment 44 associated with the two-dimensional code. Now, the user U can take out the article stored in this container compartment 44.

After the outer doors 5 and 6 are opened by the user U to take out the article, when the outer doors 5 and 6 are closed by the user U, the outer-door open-close sensor 10 detects that the outer doors 5 and 6 have been closed (step SA6).

Then, the outer-door open-close sensor 10 transmits a signal indicating that the outer doors 5 and 6 were opened and then closed, to the storage-apparatus control terminal 95.

When the storage-apparatus control terminal 95 receives this signal, the storage-apparatus control terminal 95 controls the electronic lock 9 to lock the outer doors 5 and 6 (step SA7).

After that, the storage-apparatus control terminal 95 obtains the detection result by the infrared sensor 50 of the container compartment 44 associated with the two-dimensional code (step SA8).

Based on the detection result by the infrared sensor 50, obtained at step SA8, the storage-apparatus control terminal 95 determines whether an article is stored inside all the container compartments 44 associated with the two-dimensional code, in other words, whether the insides of all the container compartments 44 associated with the two-dimensional code are vacant (step SA9).

If it is determined that the insides of all the container compartments 44 associated with the two-dimensional code are vacant (step SA9: YES), the storage-apparatus control terminal 95 cancels the associated relations between the obtained two-dimensional code and all the container compartments 44 associated with this two-dimensional code (step SA10).

If it is determined that the insides of all the container compartments 44 associated with the two-dimensional code are not vacant (step SA9: NO), the storage-apparatus control terminal 95 determines whether there is a container compartment 44 inside which an article is not stored, among the container compartments 44 associated with the two-dimensional code, in other words, whether the inside of any of the container compartments 44 associated with the two-dimensional code is vacant (step SA11).

If it is determined that the inside of any of the container compartments 44 associated with the two-dimensional code is vacant (step SA11: YES), the storage-apparatus control terminal 95 cancels the associated relation between the obtained two-dimensional code and the container compartment 44 that is associated with the two-dimensional code and the inside of which is vacant (step SA12).

Note that at step SA11, the storage-apparatus control terminal 95 keeps the associated relation between the container compartments 44 determined to be not vacant and the two-dimensional code associated with these container compartments 44.

Then, the storage-apparatus control terminal 95 determines whether a specified time has elapsed since the obtaining unit 8 obtained the two-dimensional code (step SA13).

If it is determined that a specified time has elapsed since the obtaining unit 8 first obtained the two-dimensional code associated with the specified container compartments 44 (step SA13: YES), the storage-apparatus control terminal 95 cancels the associated relation between this two-dimensional code and all the container compartments 44 associated with this two-dimensional code (step SA14).

If it is determined that a specified time has not elapsed since the obtaining unit 8 first obtained the two-dimensional code associated with the specified container compartments 44 (step SA13: NO), the storage-apparatus control terminal 95 keeps the associated relation between this two-dimensional code and all the container compartments 44 associated with this two-dimensional code.

At step SA4, if the obtained two-dimensional code is not associated with any container compartment 44 (step SA4: NO), the storage-apparatus control terminal 95 displays an indication that the presented two-dimensional code is not associated with any container compartment 44, in other words, what is called an error message, on the touch panel 7 (step SA15).

[1-3. Advantageous Effects and Some Other Information]

As has been described above, the storage apparatus 1 in the present embodiment has the opening 4A open to the front and includes the container compartments 44 capable of storing articles inside, the obtaining unit 8 that obtains two-dimensional codes, and the storage-apparatus control terminal 95 that associates articles with specified information. Then, in the case in which a specified time has elapsed since the storage-apparatus control terminal 95 received a specified signal indicating that the obtaining unit 8 obtained the two-dimensional code, the storage-apparatus control terminal 95 cancels the associated relation between the container compartments 44 and the two-dimensional code.

With this configuration, in the storage apparatus 1, it is possible to unlock the electronic lock 9 repeatedly within the specified time by presenting the two-dimensional code to the obtaining unit 8. Thus, since the associated relation between the container compartments 44 and the two-dimensional code is not canceled within the specified time, the storage apparatus 1 can prevent the user U from forgetting to take out articles.

In addition, as described above, the storage apparatus 1 has means for canceling the associated relation between the container compartments 44 and the two-dimensional code if a specified time has elapsed. Thus, the storage apparatus 1 can prevent articles for being stored continuously inside the display room 4, and in turn improve the operating ratio of the display room 4.

As in the present embodiment, the storage apparatus 1 may have the infrared sensors 50 capable of detecting the internal states of the container compartments 44, and based on the obtained detection results by the infrared sensors 50, the storage-apparatus control terminal 95 may determine whether articles are stored inside container compartments 44. If it is determined that articles are not stored inside the container compartments 44, the storage-apparatus control terminal 95 may cancel the associated relation between the container compartments 44 and the two-dimensional code.

With this configuration, the storage apparatus 1 can cancel the associated relation between the container compartments 44 in which articles have been taken out and the two-dimensional code associated with these container compartments 44. Thus, for the storage apparatus 1, it is possible to store new articles in vacant container compartments 44 in the storage apparatus 1 without waiting for a specified time, and this can improve the operating ratio.

As in the present embodiment, the storage-apparatus control terminal 95 may associate a two-dimensional code with a plurality of container compartments 44, and in the case in which it determines that an article is not stored in at least one of the container compartments 44, the storage-apparatus control terminal 95 may cancel the associated relation between the container compartment 44 determined to be not storing an article and the two-dimensional code.

With this configuration, even if a two-dimensional code is associated with a plurality of container compartments 44, the storage apparatus 1 can cancel the associated relation between the container compartment 44 from which the article has been taken out and the two-dimensional code associated with this container compartment 44. Thus, for the storage apparatus 1, it is possible to store a new article in a vacant container compartment 44 in the storage apparatus 1 without waiting for a specified time, and this improves the operating ratio.

As in the present embodiment, the storage apparatus 1 includes the openable outer doors 5 and 6 that close the opening 4A and the electronic lock 9 that locks and unlocks the outer doors 5 and 6. Then, the storage-apparatus control terminal 95 may, in the case in which an article associated with a two-dimensional code is stored inside the display room 4, make the electronic lock 9 unlock the outer doors 5 and 6.

With this configuration in the storage apparatus 1, the user U who presented a specified two-dimensional code can take out an article stored inside the display room 4. This ensures that the storage apparatus 1 can provide the user U who ordered or purchased with this article.

As in the present embodiment, in the storage apparatus 1, in the case in which a two-dimensional code associated with an article is obtained by the obtaining unit 8, a specified signal may be transmitted from the obtaining unit 8 to the storage-apparatus control terminal 95.

With this configuration in the storage apparatus 1, it is possible to cancel, after a specified time has elapsed since a two-dimensional code associated with an article is presented to the obtaining unit 8, the associated relation between this two-dimensional code and the container compartment 44. Thus, for the storage apparatus 1, it is possible to unlock the electronic lock 9 repeatedly within the specified time by presenting the two-dimensional code to the obtaining unit 8.

### Embodiment 2

Next, Embodiment 2 of the present disclosure will be described.

In Embodiment 2, the configurations of the storage apparatus 1 and the storage-apparatus control terminal 95 are the same as or similar to those in Embodiment 1, and thus, FIGS. 2 and 3 will be used to describe Embodiment 2.

[2-1. Configuration]

[2-1-1. Configuration of Storage-Apparatus Management System]

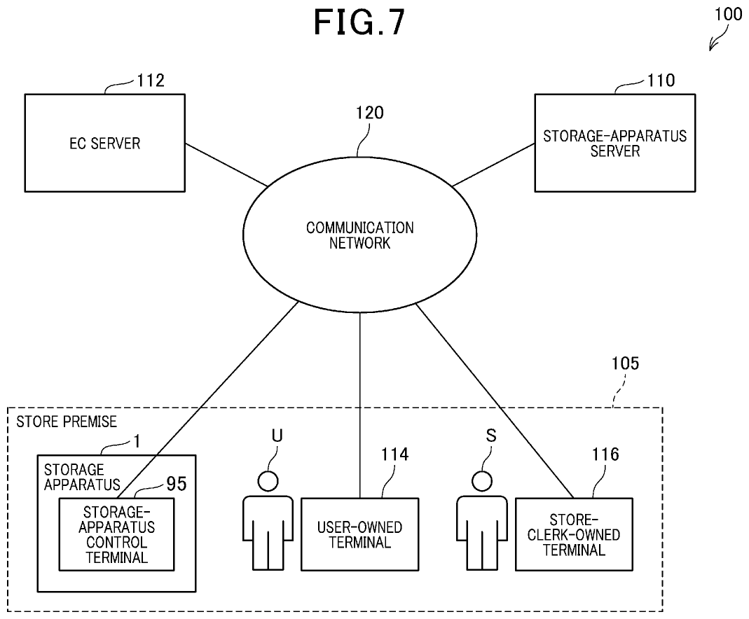

FIG. 7 is a diagram illustrating a schematic configuration of a storage-apparatus management system 100 of Embodiment 2.

The storage-apparatus management system 100 processes information for managing the storage apparatus 1. The storage-apparatus management system 100 includes the storage apparatus 1, a storage-apparatus server 110, and an EC server 112. The present embodiment is described based on a case in which the system includes one storage apparatus 1 and one server 1, but the configuration is not limited to this. The number of apparatuses and servers managed by the storage-apparatus management system 100 may be plural.

The communication network 120 connects the devices included in the storage-apparatus management system 100, such as the storage apparatus 1 and the storage-apparatus server 110, so that these devices can perform data communication with each other. The communication network 120 may include public line networks, dedicated lines, and various wireless communication lines and may also include devices such as servers, routers, and wireless communication access points. The connection between the devices included in the storage-apparatus management system 100 and the communication network 120 may be wireless or may be wired.

The EC server 112 is an external server that provides EC websites (EC sites) for purchasing products and the like through electronic commerce (EC).

The EC server 112 can communicate with various terminals, such as smartphones, and servers via the communication network 120, and the EC server 112 can receive purchasing or orders of articles from various terminals and transmit two-dimensional codes associated with these articles to the terminals.

The EC server 112 can also make specified notifications to various terminals. In the present embodiment, the EC server 112 communicates with the storage-apparatus control terminal 95 via the storage-apparatus server 110.

Note that the storage-apparatus management system 100 may include not only the EC server 112 but also various web servers, local servers, and the like.

The storage-apparatus server 110 obtains various kinds of information from the storage-apparatus control terminal 95 and transmits the information to various servers and terminals via the communication network 120.

In the present embodiment, the storage-apparatus server 110 transmits various kinds of information obtained from the storage-apparatus control terminal 95 to the EC server 112.

Note that the storage-apparatus server 110 may have a function as a storage unit that stores authentication information that allows operation of the storage apparatus 1, the inventory condition of the storage apparatus 1, various kinds of information concerning the articles that are stored in the container compartments 44, such as prices, the dates when the articles were stored into the container compartments 44, and the temperatures inside the compartment when articles are stored, and other information.

For example, the storage-apparatus server 110 may obtain these kinds of information from the storage apparatus 1, the EC server 112, and the outside of the storage-apparatus management system 100 via the communication network 120, and may store them in it.

The storage-apparatus server 110 may be integrated with the storage apparatus 1 or the storage-apparatus control terminal 95.

In the storage-apparatus management system 100 of the present embodiment, the storage apparatus 1 is installed at a store premise 105 such as a convenience store or a concession stand.

The storage-apparatus control terminal 95, as described above, controls each unit of the storage apparatus 1 and also transmits various kinds of obtained information to the storage-apparatus server 110 via the communication network 120.

The storage-apparatus management system 100 can receive connection from a user-owned terminal 114 owned by a user U who purchases an article stored inside the storage apparatus 1 and a store-clerk-owned terminal 116 owned by a store clerk S. The user-owned terminal 114 and the store-clerk-owned terminal 116 have data communication functions and perform data communication with the storage apparatus 1 and the foregoing servers.

The user-owned terminal 114 and the store-clerk-owned terminal 116 are mobile terminals capable of communicating with the EC server 112 to performs purchase processing for an article, and these user-owned terminal 114 and store-clerk-owned terminal 116 are, for example, mobile phones, smartphones, tablets, or the like.

These user-owned terminal 114 and store-clerk-owned terminal 116 can execute specified application programs related to the storage-apparatus management system 100. In the present embodiment, these the user-owned terminal 114 and store-clerk-owned terminal 116 are capable of displaying two-dimensional codes which are the specified information.

Here, in the storage-apparatus management system 100, the store clerk S is a management worker who manages the storage apparatus 1 and articles stored in the storage apparatus 1. The store clerk S is, for example, a store clerk S working at the store premise 105, an installation worker who installs the storage apparatus 1, a management worker for managing the storage apparatus 1 and the storage-apparatus management system 100, or a like worker. In other words, the store clerk S is a worker who provides maintenance of the storage apparatus 1, puts and takes articles into and out of the storage apparatus 1, and manages the inventory of stored articles.

The store-clerk-owned terminal 116 is capable of displaying authentication information that identifies the store clerk S. In the present embodiment, the authentication information is in the form of a two-dimensional code.

The user U uses various services provided by the storage apparatus 1 and/or the storage-apparatus management system 100, such as purchasing an article stored in the storage apparatus 1.

Note that the number of user-owned terminals 114 and the number of store-clerk-owned terminals 116 included in the storage-apparatus management system 100 are not limited to any specific ones.

[2-2. Operation]

The operation of the storage apparatus 1 and the storage-apparatus management system 100 having the configurations described above will be described below.

[1-2-1. Operation when Article is Purchased and Put into Storage Apparatus]

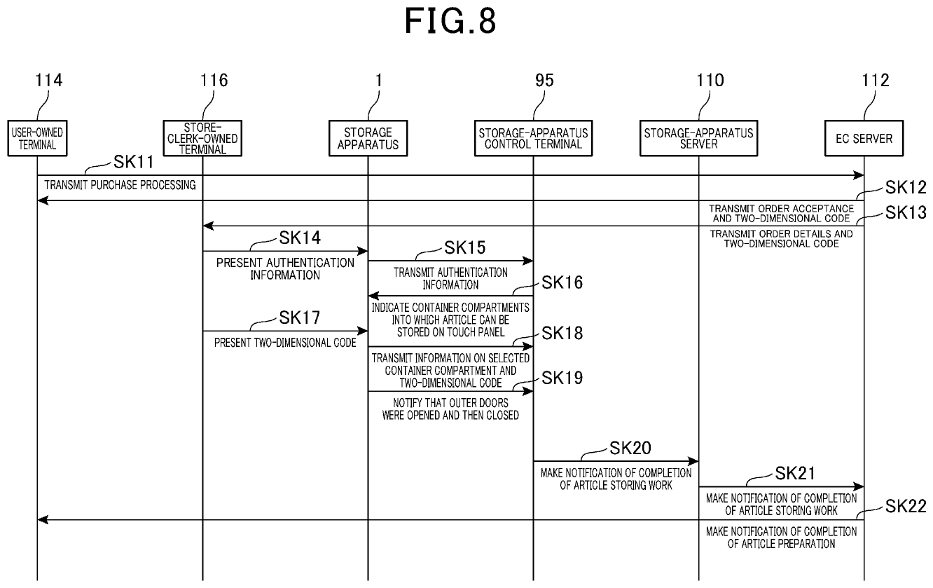

FIG. 8 is a sequence diagram illustrating operation of the storage-apparatus management system 100.

Based on FIG. 8, a description will be given of the operation of the storage-apparatus management system 100 for the case in which an article is purchased and put into the storage apparatus 1.

First, when the user U orders an article, the user U uses the user-owned terminal 114 to communicate with the EC server 112, and performs purchase processing for an article, according to displays and instructions on the EC site (step SK11).

When the EC server 112 receives the purchase processing transmitted from the user-owned terminal 114, the EC server 112 transmits information indicating that the purchase processing has been accepted, in other words, an order acceptance, to the user-owned terminal 114. The EC server 112 transmits, along with the order acceptance, a two-dimensional code associated with the article purchased by the user U to the user-owned terminal 114 (step SK12).

Further, the EC server 112 transmits, to the store-clerk-owned terminal 116, information on the article purchased by the user U, in other words, the order details, and a two-dimensional code associated with the article purchased by the user U (step SK13).

When the store clerk S receives the order details and the two-dimensional code, the store clerk S presents authentication information that identifies the store clerk S to the obtaining unit 8 (step SK14).

Obtaining the authentication information, the obtaining unit 8 transmits the authentication information to the storage-apparatus control terminal 95 (step SK15).

Obtaining the authentication information, the storage-apparatus control terminal 95 unlocks the electronic lock 9 and indicates, on the touch panel 7, the container compartments 44 in which an article is not stored, in other words, the container compartments 44 into which an article can be stored (step SK16).

The store clerk S opens the outer doors 5 and 6 and puts the article into a specified container compartment 44 according to the display of the touch panel 7, in other words, the store clerk S does storing work. When the storing work is completed, the store clerk S closes the outer doors 5 and 6 and presents the two-dimensional code that the store-clerk-owned terminal 116 has received to the obtaining unit 8 (step SK17).

The storage-apparatus control terminal 95 obtains the detection results by the infrared sensors 50, in other words, the container compartment 44 selected to put in the article, and the two-dimensional code obtained by the obtaining unit 8 (step SK18).

Further, when the storage-apparatus control terminal 95 obtains a signal indicating that the outer doors 5 and 6 were opened and then closed from the outer-door open-close sensor 10 (step SK19), the storage-apparatus control terminal 95 associates the container compartment 44 selected to put in the article and the two-dimensional code obtained by the obtaining unit 8.

When the foregoing relation association is completed, the storage-apparatus control terminal 95 notifies the storage-apparatus server 110 of the completion of the article storing work (step SK20).

The storage-apparatus server 110, receiving the notification of the completion of the article storing work, notifies the EC server 112 of the completion of the article storing work (step SK21).

The EC server 112, receiving the notification of the completion of the article storing work, notifies the user-owned terminal 114 that the article has been prepared (step SK22).

[2-2-2. Operation when Article is Taken Out of Storage Apparatus]

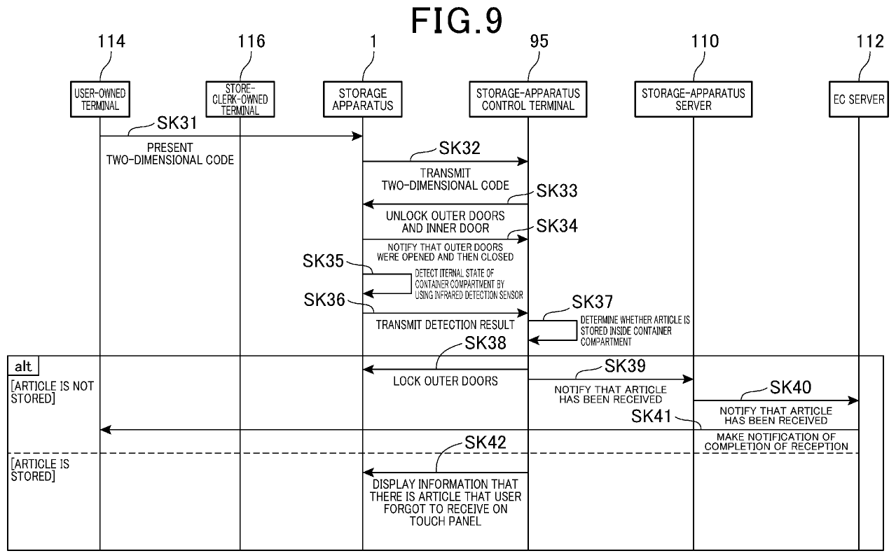

FIG. 9 is a sequence diagram illustrating operation of the storage-apparatus management system 100.

Based on FIG. 9, a description will be given of the operation of the storage-apparatus management system 100 for the case in which an article is taken out of the storage apparatus 1.

First, for the user U to receive an article from the storage apparatus 1, the user U presents a two-dimensional code displayed on the user-owned terminal 114 to the obtaining unit 8 of the storage apparatus 1 (step SK31).

The obtaining unit 8 transmits the obtained two-dimensional code to the storage-apparatus control terminal 95 (step SK32).

The storage-apparatus control terminal 95, obtaining the two-dimensional code, unlocks the electronic lock 9 and the electric lock mechanism 71 of the container compartment 44 associated with the two-dimensional code (step SK33).

When the electronic lock 9 and the electric lock mechanism 71 are unlocked, the user U opens the outer doors 5 and 6 and the inner door 61 of the container compartment 44 associated with the two-dimensional code. Now, the user U can take out the article stored in this container compartment 44.

After the outer doors 5 and 6 are opened by the user U to take out the article, when the outer doors 5 and 6 are closed by the user U, the outer-door open-close sensor 10 transmits a signal indicating that the outer doors 5 and 6 were opened and then closed to the storage-apparatus control terminal 95 (step SK34).

At this time, the infrared sensor 50 of the container compartment 44 associated with the two-dimensional code detects the internal state of this container compartment 44 (step SK35) and transmits this detection result to the storage-apparatus control terminal 95 (step SK36).

The storage-apparatus control terminal 95, obtaining this detection result, determines whether an article is stored inside the container compartment 44 associated with the two-dimensional code (step SK37).

If it is determined at step SK37 that an article is not stored, the storage-apparatus control terminal 95 makes the electronic lock 9 lock the outer doors 5 and 6 (step SK38) and notifies the storage-apparatus server 110 that the article was received by the user U (step SK39).

The storage-apparatus server 110, receiving the notification that the article was received by the user U, notifies the EC server 112 that the article was received by the user U (step SK40).

The EC server 112, receiving the notification that the article has been received by the user U, notifies the user-owned terminal 114 that the article has been received by the user U (step SK41).

At step SK37, if it is determined that an article is stored, the storage-apparatus control terminal 95 display a screen on the touch panel 7 indicating that there is an article that the user forgot to receive (step SK42).

Note that the configuration is not limited to this, but the storage-apparatus control terminal 95 may control the flashing pattern of the interior illumination light 99, the guide lights 92, or the like to notify the user U that there is an article that the user U forgot to receive. For example, the storage apparatus 1 may include a sound output device such as a speaker and may make a notification by specified sound or the like outputted from this sound output device.

[2-3. Advantageous Effects and Some Other Information]

As has been described above, the storage apparatus 1 in the present embodiment includes the display room 4 capable of storing articles inside, the infrared sensors 50 capable of detecting the internal state of the display room 4, the outer doors 5 and 6, the outer-door open-close sensor 10 that detects the opening and closing of the outer doors 5 and 6, and the electronic lock 9 that locks and unlocks the outer doors 5 and 6. The storage apparatus 1 also includes the storage-apparatus control terminal 95 that in the case of receiving a specified signal, determines based on the detection results by the infrared sensors 50 whether an article is stored inside the container compartment 44 provided in the display room 4. Then, if the storage-apparatus control terminal 95 determines based on the detection results by the infrared sensors 50 that an article is not stored inside the container compartment 44, the storage-apparatus control terminal 95 makes the electronic lock 9 lock the outer doors 5 and 6.

With this configuration, the storage apparatus 1 can detect the internal state of the container compartment 44 by using the infrared sensor 50. Thus, the storage apparatus 1 can determine whether the article stored in the container compartment 44 has been taken out.

Further, the storage apparatus 1 can lock the outer doors 5 and 6 if the user U took out the article associated with the two-dimensional code that the user U presented. This configuration prevents a situation in which the user U cannot take out the article that the user U forgot to take out of the display room 4.

For the storage apparatus 1 in the present embodiment, in the case in which the outer-door open-close sensor 10 receives a detection signal indicating that the outer doors 5 and 6 have been closed, the storage-apparatus control terminal 95 determines whether an article is stored inside the container compartment 44 provided in the display room 4.

With this operation, the storage-apparatus control terminal 95 can determine whether an article is stored inside the container compartment 44, based on the opening and closing of the outer doors 5 and 6 which inevitably occur when an article is put in or taken out the storage apparatus 1. Thus, it is possible to reliably determine whether the user U forgot to take a specified article out of the display room 4.

As in the present embodiment, the storage apparatus 1 may include the touch panel 7, and in the case in which it is determines based on the detection result by the infrared sensor 50 that an article is stored inside a specified container compartment 44, the storage-apparatus control terminal 95 may make the touch panel 7 output a display screen indicating that there is an article that the user U forgot to receive.

With this operation, the storage apparatus 1 can notify the user U that the user U forgot to receive an article. Thus, the storage apparatus 1 can prevent the user U from forgetting to receive an article.

In the present embodiment, the storage-apparatus management system 100 includes the storage apparatus 1, the storage-apparatus control terminal 95, and the storage-apparatus server 110 that communicates with the storage apparatus 1. In the case in which it is determined based on the detection result by the infrared sensor 50 that an article is not stored inside the display room 4, the storage-apparatus control terminal 95 transmits the determination result by the storage-apparatus control terminal 95 to the storage-apparatus server 110. When the storage-apparatus server 110 receives the determination result by the storage-apparatus control terminal 95, the storage-apparatus server 110 transmits specified information to the user-owned terminal 114 and the EC server 112 that can communicate with the store-clerk-owned terminal 116.

With this configuration, the storage apparatus 1 can communicate with the EC server 112 via the storage-apparatus server 110. Thus, the storage apparatus 1 can notify the user-owned terminal 114 and the store-clerk-owned terminal 116 of the internal state of the display room 4 via the storage-apparatus server 110 and the EC server 112. In other words, the storage-apparatus management system 100 can improve the convenience of the user U and the management worker such as the store clerk S.

In the present embodiment, the storage-apparatus management method is executed by the storage apparatus 1, the storage-apparatus control terminal 95, and the storage-apparatus server 110 that communicates with the storage apparatus 1.

In the storage-apparatus management method, in the case in which the storage-apparatus control terminal 95 receives a specified signal, the storage-apparatus control terminal 95 determines based on the internal state of the display room 4 whether an article is stored inside the display room 4. Then, when the storage-apparatus server 110 obtains the determination result by the storage-apparatus control terminal 95, the storage-apparatus server 110 transmits specified information to the user-owned terminal 114 and the EC server 112 that can communicate with the store-clerk-owned terminal 116.

With this configuration, the storage apparatus 1 can communicate with the EC server 112 via the storage-apparatus server 110. Thus, the storage apparatus 1 can notify the user-owned terminal 114 and the store-clerk-owned terminal 116 of the internal state of the display room 4 via the storage-apparatus server 110 and the EC server 112. In other words, the storage-apparatus management method can improve the convenience of the user U and the management worker such as the store clerk S.

### Other Embodiments

As described above, Embodiment 1 and Embodiment 2 have been described as examples of techniques that this patent application discloses. However, the techniques in the present disclosure are not limited to these examples but can be applied to embodiments obtained by making modification, replacement, addition, omission, or the like on these examples. The constituents described in the above Embodiment 1 can be combined to make a new embodiment. Further, Embodiment 1 and Embodiment 2 may be combined.

From the point of view above, other embodiments will be described below as examples.

The units illustrated in FIGS. 3, 4, and 7 in the foregoing embodiments are examples, and thus, concrete implementation configurations are not limited to those examples. Specifically, there does not have to be pieces of hardware corresponding to those units, respectively. The functions of those units can be implemented by one processor executing a program, as a matter of course. In the above embodiments, part of the functions implemented by using software may be implemented by using hardware, or part of the functions implemented by using hardware may be implemented by using software. In addition, concrete detailed configurations of the storage-apparatus control terminal 95 and the other units in the storage apparatus 1 can be modified as appropriate within the scope not departing from the spirit of the present disclosure.

In addition, for example, the step units in the operation illustrated in FIGS. 5, 6, 8, and 9 were determined by dividing the operation based on main processes to make it easy to understand the operation of the storage-apparatus control terminal 95 and the storage-apparatus management system 100. Hence, the present invention is not limited by the names of the process units or the way of dividing to determine the process units. The operation may be divided into a larger number of step units according to the process details. The operation may be divided such that one step unit has a larger number of processes. The order of the steps may be changed as appropriate as long as it does not create any contradiction to the spirit of the present disclosure.

Note that the foregoing embodiments are to show examples of the techniques in the present disclosure, and thus various kinds of modification, replacement, and addition, omission can be made on them within the scope of the claims or the equivalents thereof.

The present disclosure is applicable to storage apparatuses including an input unit to which specified information is inputted and a control unit that associates articles and specified information. Specifically, the present disclosure is applicable to sales showcases, lockers for receiving or storing articles, and the like.

### REFERENCE SIGNS LIST

1 storage apparatus
4, 4L, 4R display room
4A opening
5, 6 outer door (door)
7 touch panel (notification unit)
8 obtaining unit (input unit)
9 electronic lock (lock mechanism)
10 outer-door open-close sensor (open-close detection unit)
44 container compartment
50 infrared sensor (article detection unit)
95 storage-apparatus control terminal (control unit)

What is claimed is:

1. A storage apparatus comprising:
a display room having an opening open to the front and capable of storing an article inside;
an input unit into which specified information associated with the article is inputted; and
a control unit that associates the display room with the specified information, wherein
the control unit cancels the associated relation between the display room and the specified information in a case in which a specified time has elapsed since the control unit received a specified signal.

2. The storage apparatus according to claim 1, further comprising
an article detection unit capable of detecting an internal state of the display room, wherein
the control unit obtains a detection result by the article detection unit, and based on the obtained detection result, determines whether the article is stored inside the display room, and if the control unit determines that the article is not stored inside the display room, the control unit cancels the associated relation between the display room and the specified information.

3. The storage apparatus according to claim 1, wherein
the display room has a plurality of container compartments capable of storing the article, and
the control unit associates the specified information with at least one of the container compartments, and the control unit cancels the associated relation between the container compartment and the specified information in a case in which a specified time has elapsed since the control unit received a specified signal.

4. The storage apparatus according to claim 3, further comprising
an article detection unit capable of detecting an internal state of the display room, wherein
the control unit obtains a detection result by the article detection unit, and based on the obtained detection result, determines whether the article is stored inside the display room, and
the control unit associates the specified information with the plurality of container compartments, and in a case in which the control unit determines that the article is not stored inside at least one of the container compartments, the control unit cancels the associated relation between the container compartment determined to be not storing the article and the specified information.

5. The storage apparatus according to claim 1, further comprising:
a door provided at the front of the display room and capable of opening and closing; and
a lock mechanism that locks and unlocks the door, wherein
in a case in which the article associated with information inputted into the input unit is stored inside the display room, the control unit makes the lock mechanism unlock the door.

6. The storage apparatus according to claim 1, wherein
in a case in which the specified information associated with the article is inputted into the input unit, the specified signal is transmitted from the input unit to the control unit.

7. A storage apparatus comprising:
a display room having an opening open to the front and capable of storing an article inside;
an article detection unit capable of detecting an internal state of the display room;
an openable door that closes the opening;
an open-close detection unit that detects opening and closing of the door;
a lock mechanism that locks and unlocks the door; and
a control unit that, in a case of receiving a specified signal, determines based on a detection result by the article detection unit whether the article is stored inside the display room, wherein
in a case in which the control unit determines based on a detection result by the article detection unit that the article is not stored inside the display room, the control unit makes the lock mechanism lock the door.

8. A storage apparatus comprising:
a display room having an opening open to the front and capable of storing an article inside;
an article detection unit capable of detecting an internal state of the display room;
an openable door that closes the opening;
an open-close detection unit that detects opening and closing of the door;
a notification unit that outputs a specified notification; and
a control unit that, in a case of receiving a specified signal, determines based on a detection result by the article detection unit whether the article is stored inside the display room, wherein
in a case in which the control unit determines based on a detection result by the article detection unit that the article is stored inside the display room, the control unit makes the notification unit output a specified notification.

9. A storage-apparatus management system comprising:
a storage apparatus including a display room having an opening open to the front and capable of storing an article inside and an article detection unit capable of detecting an internal state of the display room;
a control unit that, in a case of receiving a specified signal, determines based on a detection result by the article detection unit whether the article is stored inside the display room; and
a storage-apparatus server that communicates with the storage apparatus, wherein
in a case in which the control unit determines based on a detection result by the article detection unit that the article is not stored inside the display room, the control unit transmits the determination result by the control unit to the storage-apparatus server, and
in a case in which the storage-apparatus server receives the determination result by the control unit, the storage-apparatus server transmits specified information to an external server capable of communicating with a specified terminal.

10. A storage-apparatus management method executed by a storage apparatus including a display room having an opening open to the front and capable of storing an article inside, a control unit that performs specified control on the storage apparatus, and a storage-apparatus server that communicates with the storage apparatus, the method comprising:
determining, by the control unit, whether the article is stored inside the display room, based on an internal state of the display room, in a case in which the control unit receives a specified signal; and
transmitting, by the storage-apparatus server, specified information to an external server capable of communicating with a specified terminal, in a case in which the storage-apparatus server obtains the determination result by the control unit.
